(19) United States
(12) Patent Application Publication
(10) Pub. No.: US 2012/0103671 A1
(43) Pub. Date: May 3, 2012

(54) PRINTED CIRCUIT BOARD AND METHOD FOR MANUFACTURING THE SAME

(75) Inventors: Eung Suek LEE, Seoul (KR); Kwang Seop YOUM, Chungcheongbuk-do (KR); Keung Jin SOHN, Gyunggi-do (KR); Mi Sun HWANG, Gyunggi-do (KR)

(73) Assignee: SAMSUNG ELECTRO-MECHANICS CO., LTD., Gyunggi-do (KR)

(21) Appl. No.: 13/007,474

(22) Filed: Jan. 14, 2011

(30) Foreign Application Priority Data
Nov. 2, 2010 (KR) 10-2010-0108342

(51) Int. Cl. H05K 1/18; H05K 1/11; H05K 3/00; H05K 1/00

(52) U.S. Cl. 174/260; 174/250; 174/261; 29/829

(57) ABSTRACT

Disclosed herein are a printed circuit board and a method for manufacturing the same capable of implementing a slim and small semiconductor package by the printed circuit board configured to include a circuit layer and an insulating layer as a single layer and shortening a process time and reducing processing costs by forming a bump using a screen printing method. Further, disclosed herein is a method for manufacturing a printed circuit board capable of improving a warpage problem of the printed circuit board that occurs during a polishing process by adopting a coining process instead of a polishing process.

### CROSS REFERENCE TO RELATED APPLICATION

This application claims the benefit of Korean Patent Application No. 10-2010-0108342, filed on Nov. 2, 2010, entitled “Printed Circuit Board And Method For Manufacturing The Same” which is hereby incorporated by reference in its entirety into this application.

### BACKGROUND OF THE INVENTION

1. Technical Field

The present invention relates to a printed circuit board and a method for manufacturing the same.

2. Description of the Related Art

With the development of the electronic industries, the use of a package in which memory chips are mounted in various kinds of electronics has rapidly increased. As the slimness of an electronic product package increases, the demand for the slim, light, and multi-functional electronic products correspondingly increases. Therefore, a demand for a slim or high-density printed circuit board, which is one of important components configuring the package, has increased. Further, as the package becomes more commonly used, package manufacturers manufacturing and supplying the package have correspondingly increased. A competitive price of the package has become a serious concern as the supply of the package is increased. Due to the market situation, research into lowering manufacturing costs of the printed circuit board configuring the package has been conducted.

FIGS. 1 to 5 are cross-sectional views sequentially showing a method for manufacturing a printed circuit board according to the prior art. The problems of the prior art will be described with reference to FIGS. 1 to 5.

Referring first to FIG. 1, a printed circuit board includes a copper clad laminate 10 wherein the copper clad laminates are stacked on both sides of an insulating layer and a through hole 20 formed by using a computerized numerical control (CNC) drill, a yttrium aluminum garnet (YAG) laser, or CO2 laser, or the like. Thereafter, copper plating is chemically performed over the copper clad laminate 10 including the through hole 20 to form a copper plating layer 15. This is a process for improving an adhesion between a conductive paste 30 filled in the through hole 20 and an inner wall of the through hole 20, to be described below.

Next, as shown in FIG. 2, the conductive paste 30 is filled in the through hole 20. Describing in detail a method of filling the conductive paste 30, a mask 33 formed with holes to expose a portion corresponding to the through hole 20 is positioned to contact one surface of the copper clad laminate 10, the conductive paste 30 is provided on the top surface of the mask 33, and the conductive paste 30 is pushed out the holes of the mask 33 by a squeeze 35. Consequently, the conductive paste 30 is also filled in the through hole 20 while being discharged from the through hole 20 via the holes of the mask 33.

Next, as shown in FIG. 3, the conductive paste 30 filled in the through hole 20 is hardened and the conductive paste 30 protruded from the copper clad laminate 10 due to overfilling and the chemical copper plating layer 15 formed on the copper clad surface are removed by a polishing process using a brush 40.

Next, as shown in FIG. 4, the chemical copper plating and the electrical copper plating are performed on the surface of the copper clad laminate 10, such that the thickness of the copper clad layer and the copper plating layer 50 is thick. The copper clad layer and the copper plating layer 50 will be formed as a circuit layer by the process to be described below. The thickness thereof is thick to improve the reliability of the circuit layer.

Next, as shown in FIG. 5, the copper clad layer and the copper plating layer 50 are removed by the selective etching to form the circuit layer 55 and a solder resist 60 is applied on both surfaces of the insulating layer to form the printed circuit board 11.

In this configuration, the printed circuit board according to the prior art requires a process of processing the through hole 20 for electrically connecting the circuit layers insulated by the insulating layer and a process of plating the inside of the through hole 20, thereby increasing the process time and the processing costs.

In addition, after the conductive paste 30 is filled in the through hole 20, a process of polishing both surfaces of the copper clad laminate 10 should be performed by the brush 40 in order to remove the overfilled conductive paste 30. However, as the demand for the slimmed printed circuit board is increased, the thickness of the copper clad laminate is basically thin. As a result, the warpage defects of the printed circuit board occur during the process of performing the polishing process.

### SUMMARY OF THE INVENTION

The present invention has been made in an effort to provide a printed circuit board and a method for manufacturing the same capable of shortening a process time for forming a bump and lowering processing costs by adopting a method for printing the bump on circuit layers, instead of a process of forming a through hole for electrically connecting the circuit layers and a process of plating the inside of the through hole.

Further, the present invention has been made in an effort to provide a slim and small printed circuit board by implementing a semiconductor package where semiconductor chips are mounted on a printed circuit board configured to include a circuit layer and an insulating layer as a single layer and a method for manufacturing the same.

According to a preferred embodiment of the present invention, there is provided a printed circuit board, including: a bump formed on one surface of a circuit layer and having a conical shape of which both surfaces are flat; and an insulating layer formed on one surface of the circuit layer to penetrate through the bump.

The printed circuit board may further include: a first solder resist formed on the other surface of the circuit layer and formed with a first solder resist to expose a pad part of the circuit layer; and a second solder resist formed on the insulating layer and formed with a second opening to expose the bump.

The printed circuit board may further include: a first solder ball formed on the pad part exposed by the first opening; and a semiconductor chip mounted on the first solder resist to be conducted with the pad part via the first solder ball.

The printed circuit board may further include a second solder ball formed on the bump exposed by the second opening.

The bump may be formed to be protruded from the surface of the insulating layer.

According to another preferred embodiment of the present invention, there is provided a method for manufacturing a printed circuit board, including: (A) printing a bump on one surface of a metal layer; (B) stacking an insulating layer on one surface of the metal layer to penetrate through the bump; (C) forming a flat surface by coining the bump exposed from the insulating layer; and (D) forming a circuit layer by patterning the metal layer.

The method for manufacturing a printed circuit board may further include, after step (D), (E) forming a first solder resist on the circuit layer and forming a second solder resist on the insulating layer.

The method for manufacturing a printed circuit board may further include, after step (E), (F) forming a first opening to expose a pad part of the circuit layer by processing the first solder resist and forming a second opening to expose the bump by processing the second solder resist.

The method for manufacturing a printed circuit board may further include, after step (F), forming a first solder ball on the pad part exposed by the first opening and mounting a semiconductor chip on the first solder resist to be conducted with the pad part via the first solder ball.

The method for manufacturing a printed circuit board may further include, after step (F), forming a second solder ball on the bump exposed by the second opening.

The bump may be formed to be protruded from the surface of the insulating layer.

### BRIEF DESCRIPTION OF THE DRAWINGS

FIGS. 1 to 5 are cross-sectional views sequentially showing a method for manufacturing a printed circuit board according to the prior art;

FIG. 6 is a cross-sectional view of a printed circuit board according to a preferred embodiment of the present invention; and

FIGS. 7 and 13 are cross-sectional views sequentially showing a method of manufacturing a printed circuit board according to a preferred embodiment of the present invention.

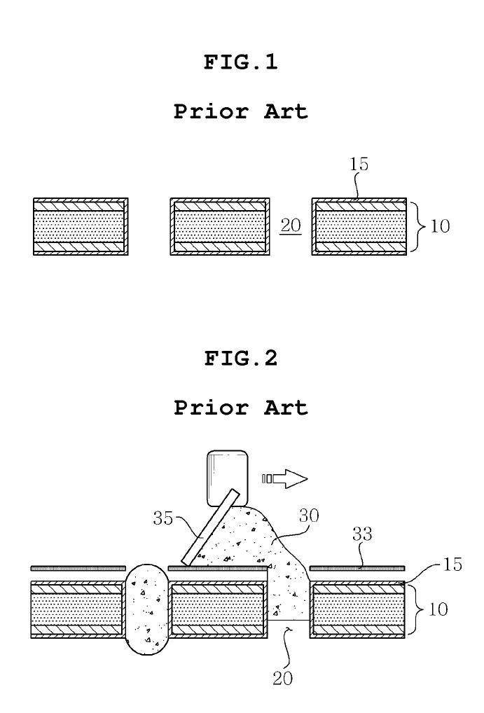

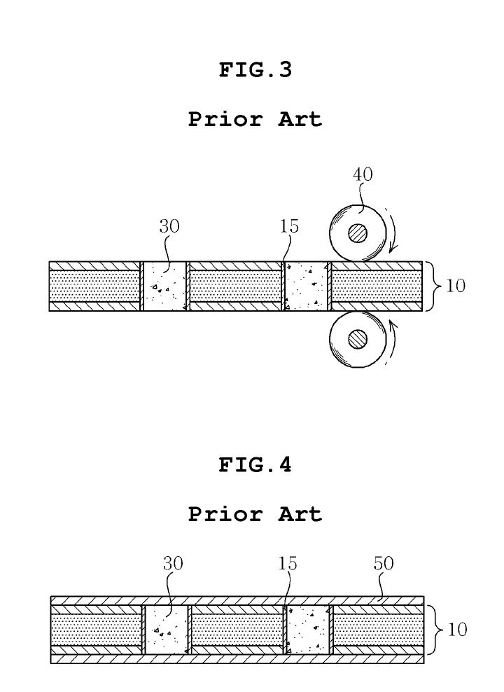

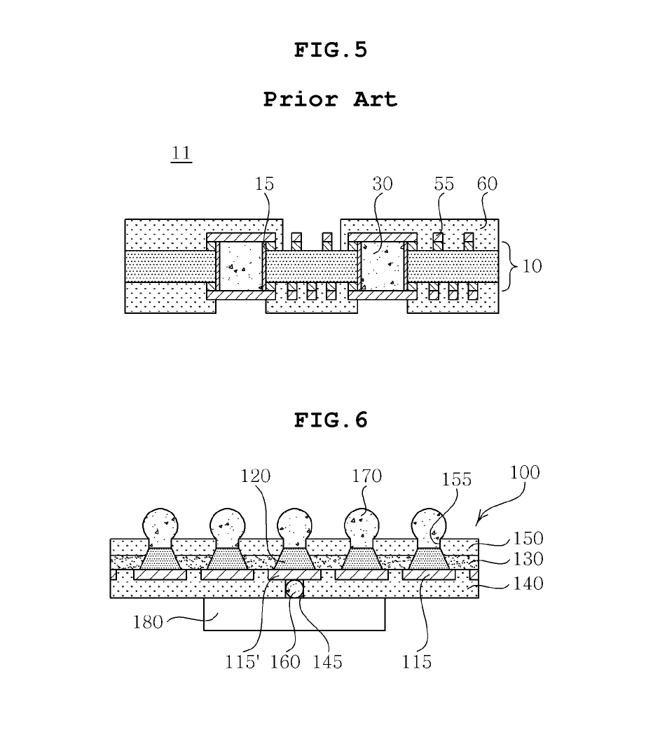

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Hereinafter, preferred embodiments according to the present invention will be described in detail with reference to the accompanying drawings.

Structure of Printed Circuit Board

FIG. 6 is a cross-sectional view of a printed circuit board according to a preferred embodiment of the present invention.

As shown in FIG. 6, a printed circuit board 100 according to a preferred embodiment of the present invention may be configured to include a circuit layer 115, a conical bump 120 formed on one surface of the circuit layer 115, an insulating layer 130 formed on one surface of the circuit layer 115, a first solder resist 140 formed on the other surface of the circuit layer 115 and formed with a first opening 145 to expose a pad part 115′ of the circuit layer 115, and a second solder resist 150 formed with the insulating layer 130 and a second opening 155 to expose the bump 120. In this configuration, the bump 120 is formed to be protruded from the surface of the insulating layer 130.

In addition, the printed circuit board 100 may further include a first solder ball 160 formed on the pad part 115′ exposed by the first opening 145 and a semiconductor chip 180 mounted on the first solder resist 140 to be conducted with the pad part 115′ via a first solder ball 160.

Further, the printed circuit board 100 may further include a second solder ball 170 formed on the bump 120 exposed by the second opening 155.

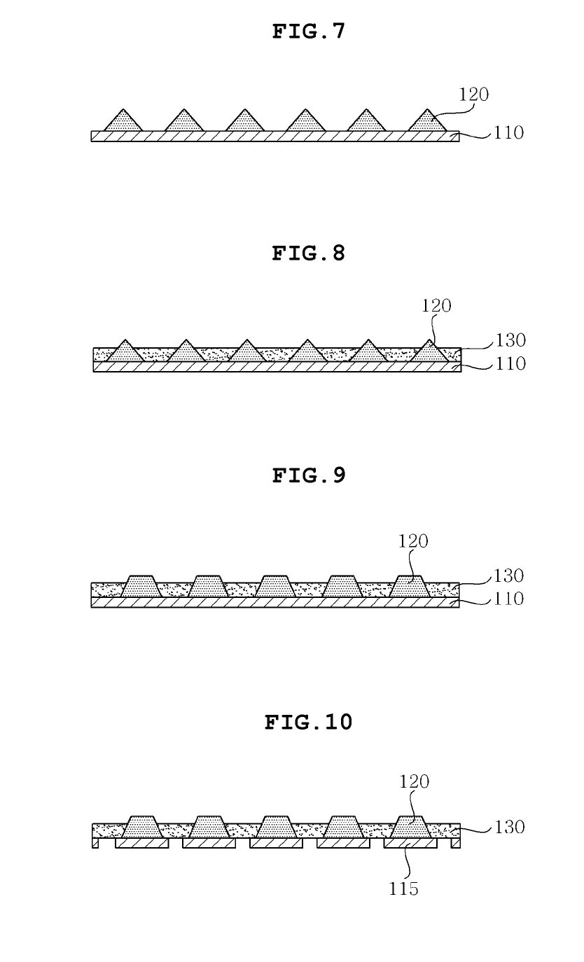

First, the circuit layer 115 is formed by selectively patterning a metal layer 110 (see FIG. 7) during the manufacturing of the printed circuit board according to the preferred embodiment. The material of the components is not limited thereto; however, it is preferable that the circuit layer is formed as a generally used copper clad. Further, the copper clad laminate has a predetermined rigidity due to the presence of the metal layer 110, such that the warpage phenomenon occurring during the processing process is suppressed.

The bump 120 is formed on one surface of the circuit layer 115 and has a conical shape of which both surfaces are flat. The bump 120 is made of a conductive paste and an example of the conductive paste forming the bump 120 may include, for example, one of Ag, Pd, Pt, Ni, and Ag/Pd. If the conductive paste is a material having conductivity, any material can be used without limitation. In addition, it is preferred that the bump 120 has a larger strength than that of the insulating layer 130 in order to penetrate through the insulating layer 130. In this configuration, the bump 120 is formed to be protruded from the surface of the insulating layer 130 to be described below. That is, the height (length between both surfaces of the bump 120) of the bump 120 is higher than the height of the insulating layer 130 (length corresponding to the thickness of the insulating layer 130).

The insulating layer 130 is formed on one surface of the metal layer 110 (see FIG. 8) in order to penetrate through the bump 120. In this case, the insulating layer 130 may be made of an insulating material generally used on the printed circuit board. For example, the insulating layer 130 may include a composite polymer resin such as prepreg (PPG), epoxy-based resin such as FR-4, BT, or the like, or Ajinomoto Build-up Film (ABF), or the like. It is preferred that the insulating layer 130 is formed to have a thickness smaller than the height of the printed bump 120.

The solder resists 140 and 150 are formed on the other surface of the circuit layer 115 and the insulating layer 130. The solder resists 140 and 150 implies a film covering the circuit pattern of the printed circuit board 100 to prevent undesired connection due to soldering performed during the mounting of components and serves as a protective material protecting the circuit pattern of the printed circuit board 100 and an insulating material insulating between the circuits. The first solder resist 140 formed on the other surface of the circuit layer 115 is provided with a first opening 145 opened to expose the pad part 115′ of the circuit layer 115. The first opening 145 is provided with the first solder ball 160 and the pad part 115′ and the semiconductor chip 180 are conducted to each other through the first solder ball 160. The second solder resist 150 formed on the insulating layer 130 is provided with the second opening 155 opened to expose the bump 120. The second opening 155 is provided with the second solder ball 170 and a motherboard or the other electronic components are electrically connected to the printed circuit board through the second solder ball 170.

The solder balls 160 and 170 are configured to electrically connect the other electronic components or the motherboard to the printed circuit board. The first solder ball 160 is attached to the first opening 145 formed on the first solder resist 140 to conduct the semiconductor chip 180 mounted on the first solder resist 140 with the circuit layer 115 of the printed circuit board and the second solder ball 170 is attached to the second opening 155 formed on the second solder resist 150 to conduct the motherboard or other electronic components with the bump 120 on the printed circuit board.

Method for Manufacturing Printed Circuit Board

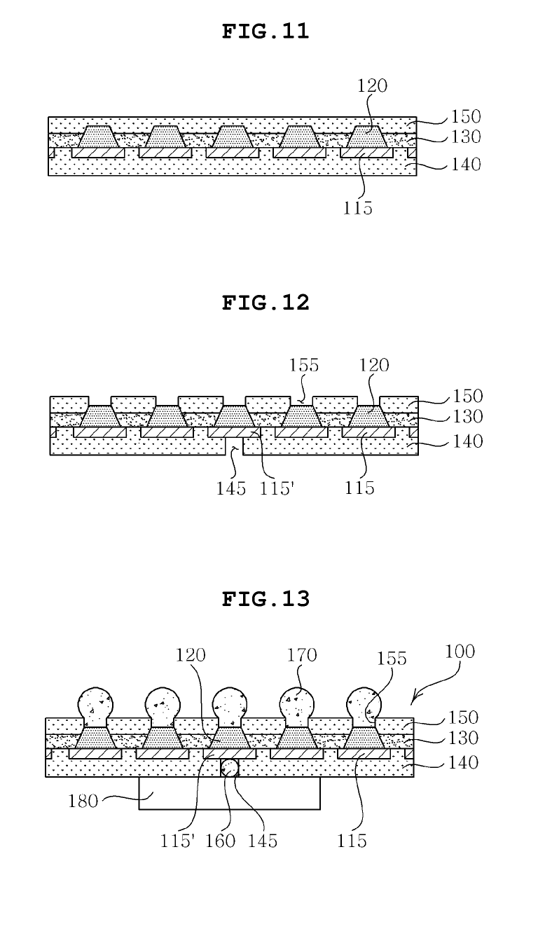

FIGS. 7 and 13 are cross-sectional views sequentially showing a method for manufacturing a printed circuit board according to a preferred embodiment of the present invention.

As shown in FIGS. 7 to 13, a method for manufacturing a printed circuit board according to the preferred embodiment is configured to include (A) printing a conical bump 120 on one surface of the metal layer 110, (B) stacking the insulating layer 130 on one surface of the metal layer 110 to penetrate through the bump 120, (C) forming a flat surface by coining the bump 120 exposed from the insulating layer 130, (D) forming the circuit layer 115 by patterning the metal layer 110, (E) forming the first solder resist 140 on the circuit layer 115 and forming the second solder resist 150 on the insulating layer 130, (F) forming the first opening 145 to expose the pad part 115′ of the circuit layer 115 by processing the first solder resist 140 and forming the second opening 155 to expose the bump 120 by processing the second solder resist 150.

First, as shown in FIG. 7, the bump 120 is printed on one surface of the metal layer 110. In this case, the bump 120 may be printed by a screen print scheme. The screen print scheme is a scheme of printing the bump 120 via a process of transferring the conductive paste through the mask formed with the opening. First, the metal layer 110 is provided and the mask formed with the opening is prepared at the same position as a position to be formed with the bump 120. After the metal layer 110 is put on the zig (not shown), the mask is disposed on the metal layer 110 while aligning the mask to match the opening of the mask at the position where the bump 120 will be printed. When the conductive paste is pushed by a squeeze, etc., from one side end of the mask to the other end thereof, the conductive paste is transferred onto the metal layer 110 while being compressed through the opening. According to the screen print scheme, it is possible to form the bump 120 in the desired height and shape by selecting the thickness or shape of the mask. In the present invention, it is preferable that the height of the bump 120 is formed to be 150 μm or more. Further, printing the bump 120 by other known methods may be considered as being included in the scope of the present invention. In this case, since the conductive paste compressed and printed has high viscosity, the conductive paste is dried through the drying process after printing the conductive paste to form the bump 120. Meanwhile, it is preferred that the bump 120 has a larger strength than that of the insulating layer 130 in order to penetrate through the insulating layer 130 to be described below.

Next, as shown in FIG. 8, the insulating layer 130 is stacked on one surface of the metal layer 110 to penetrate through the bump 120. In this case, it is preferred that the insulating layer 130 is formed to have a thickness smaller than the height of the printed bump 120. As the method of forming the insulating layer 130 on the metal layer 110, there are a contact method and a contactless method. First, the contact method is a method that disposes to face an insulating material such as semi-hardened prepreg, etc., formed in a thermosetting resin, etc., with one surface of the metal layer 110 formed with the bump 120 and physically stack the insulating material on the metal layer 110 to allow the bump 120 to penetrate through the insulating material. The contactless method is a method of coating the insulating resin powders by the inkjet print scheme to minimize the change in shape of the bump 120 or the micro gap between the bump 120 and the insulating layer 130 caused by being applied with a force generated by allowing the bump 120 to penetrate through the insulating layer 130 in the contact scheme. When the insulating layer 130 is stacked on the metal layer 110 to penetrate through the bump 120, the sharp portion of the conical bump 120 is protruded to be exposed from the surface of the insulating layer 130 by completely penetrating through the insulating layer 130.

Next, as shown in FIG. 9, the flat surface is formed by coining the bump 120 exposed from the insulating layer 130. If the bump 120 is not subjected to the coining process, the end of the bump 120 is protruded over the surface of the insulating layer 130, such that the adhesion between the bump 120 and the solder ball or the semiconductor chip 180, etc., is degraded when the end of the bump 120 contacts the solder ball or the semiconductor chip 180, etc., in a sharp state. In addition, when the conductive paste is printed on the metal layer 110 and is then subjected to the dry process, the viscosity of the bump 120 is lowered, such that electrically stable bonding is not implemented even though a predetermined pressure is applied at the moment of bonding the solder ball or the semiconductor chip 180. Therefore, the end of the bump 120 is coined by the press (not shown) of the coining process apparatus to form the flat surface, thereby making it possible to improve the reliability of bonding between the second solder ball 170 and the bump 120.

Next, as shown in FIG. 10, the metal layer 110 is patterned to form the circuit layer 115. The circuit layer 115 may be formed without performing an additional panel plating process by selecting the metal layer 110 having a predetermined thickness or more in the early time of manufacturing. In this case, the circuit layer 115 may be manufactured by using the process of forming a general circuit pattern such as the tenting method. First, the etching resist is applied on the surface of the metal layer 110 and is then patterned to form the etching resist pattern. Thereafter, the metal layer 110 is selectively etched by applying the tenting method to form the circuit layer 115 and remove the etching resist pattern.

Next, as shown in FIG. 11, the first solder resist 140 is formed on the circuit layer 115 and the second solder resist 150 is formed on the insulating layer 130. The first solder resist 140 serves to protect the circuit layer 115 and the second solder resist 150 serves to protect the insulating layer 130 and the bump 120 protruded from the insulating layer 130.

Next, as shown in FIG. 12, the first opening 145 to expose the pad part 115′ of the circuit layer 115 by processing the first solder resist 140 and the second opening 155 is formed to expose the bump 120 by processing the second solder resist 150. The first opening 145 is opened to conduct the semiconductor chip 180 with the pad part 115′ of the circuit layer 115 via the first solder ball 160. The second opening 155 is opened to conduct the motherboard or other electronic components via the second solder ball 170. The method for forming the solder resists 140 and 150 on the openings 145 and 155 uses the known technologies and the manufacturing process thereof will be described below.

First, the solder resists 140 and 150 applied on the circuit layer 115 and the insulating layer 130 are temporarily dried by a heating scheme using the drier. The copper clad laminate when the solder resists 140 and 150 are temporarily dried is closely attached with an art work film previously formed with the solder resist pattern and is then exposed to ultraviolet rays, thereby hardening the solder resists 140 and 150 of a portion corresponding to the solder resist pattern. The copper clad laminate in which the solder resist pattern is hardened is formed with the solder resist pattern by removing the solder resists 140 and 150 of a portion which is not hardened by using the developing apparatus. The copper clad laminate formed with the solder resist pattern is exposed to ultraviolet rays, thereby hardening the solder resist. Thereafter, the solder resists 140a and 150 is thermally set in a scheme of heating the copper clad laminate in which the solder resist pattern is hardened by using a drier.

Next, as shown in FIG. 13, the first solder ball 160 is formed on the pad part 115′ exposed by the first opening 145 and the semiconductor chip 180 is mounted on the first solder resist 140 to be conducted with the pad part 115′ via the first solder ball 160. Further, the second solder ball 170 is formed on the bump 120 exposed by the second opening 155. The method for forming the solder balls 160 and 170 may use the known technologies. As the representative known technologies, there are a melting soldering method contacting the pad electrode to the melting soldering, a screen printing method screen-printing and reflowing the solder paste, a solder ball method mounting the solder ball on the pad electrode and reflowing it, and a plating method performing the soldering plating on the pad electrode, etc.

According to the present invention, the printed circuit board is configured to include the circuit layer and the insulating layer as a single layer to mount the semiconductor chips on the printed circuit board, thereby making it possible to implement the slim and small semiconductor package.

Further, the present invention does not need the process of forming the through hole and plating the inside of the through hole in order to electrically connect the circuit layers, thereby making it possible to shorten the process time consumed to form the bump and efficiently reduce the processing costs.

Further, the present invention adopts the coining process instead of the polishing process, thereby making it possible to improve the warpage problem of the printed circuit board generated during the process of performing the polishing process.

Although the embodiments of the present invention regarding the touch panel have been disclosed for illustrative purposes, those skilled in the art will appreciate that a variety of different modifications, additions and substitutions are possible, without departing from the scope and spirit of the invention as disclosed in the accompanying claims.

Accordingly, such modifications, additions and substitutions should also be understood as falling within the scope of the present invention.

What is claimed is:

1. A printed circuit board, comprising:
a bump formed on one surface of a circuit layer and having a conical shape of which both surfaces are flat; and
an insulating layer formed on one surface of the circuit layer to penetrate through the bump.

2. The printed circuit board as set forth in claim 1, further comprising:
to a first solder resist formed on the other surface of the circuit layer and formed with a first opening to expose a pad part of the circuit layer; and
a second solder resist formed on the insulating layer and formed with a second opening to expose the bump.

3. The printed circuit board as set forth in claim 2, further comprising:
a first solder ball formed on the pad part exposed by the first opening; and
a semiconductor chip mounted on the first solder resist to be conducted with the pad part via the first solder ball.

4. The printed circuit board as set forth in claim 2, further comprising a second solder ball formed on the bump exposed by the second opening.

5. The printed circuit board as set forth in claim 1, wherein the bump is formed to be protruded from the surface of the insulating layer.

6. A method for manufacturing a printed circuit board, comprising:
(A) printing a bump on one surface of a metal layer;
(B) stacking an insulating layer on one surface of the metal layer to penetrate through the bump;
(C) forming a flat surface by coining the bump exposed from the insulating layer; and
(D) forming a circuit layer by patterning the metal layer.

7. The method for manufacturing a printed circuit board as set forth in claim 6, further comprising, after step (D), (E) forming a first solder resist on the circuit layer and forming a second solder resist on the insulating layer.

8. The method for manufacturing a printed circuit board as set forth in claim 7, further comprising, after step (E), (F) forming a first opening to expose a pad part of the circuit layer by processing the first solder resist and forming a second opening to expose the bump by processing the second solder resist.

9. The method for manufacturing a printed circuit board as set forth in claim 8, further comprising: after step (F),
forming a first solder ball on the pad part exposed by the first opening and mounting a semiconductor chip on the first solder resist to be conducted with the pad part via the first solder ball.

10. The method for manufacturing a printed circuit board as set forth in claim 8, further comprising, after step (F), forming a second solder ball on the bump exposed by the second opening.

11. The method for manufacturing a printed circuit board as set forth in claim 6, wherein the bump is formed to be protruded from the surface of the insulating layer.
